(19) United States
(12) Patent Application Publication
(10) Pub. No.: US 2026/0255767 A1
(43) Pub. Date: Aug. 27, 2026

(54) LIGHT-EMITTING DEVICE

(71) Applicant: Ennostar Corporation, Hsinchu City (TW)

(72) Inventors: Yin-Cyuan WU, Hsinchu City (TW); Sheng-Fu WANG, Hsinchu City (TW); Sheng-Pei LIN, Hsinchu City (TW); Wen-Yu LEE, Hsinchu City (TW)

(21) Appl. No.: 19/541,162

(22) Filed: Feb. 16, 2026

(30) Foreign Application Priority Data
Feb. 24, 2025 (TW) 114106692

(51) Int. Cl. H10H 29/855; H10H 29/851; H10H 29/853

(52) U.S. Cl. CPC H10H 29/8552; H10H 29/851; H10H 29/853

(57) ABSTRACT

A light-emitting device is provided. The light-emitting device includes a substrate, a light-emitting element, an encapsulating layer, and a light-adjusting structure. The light-emitting element is disposed on the substrate. The light-emitting element includes a light-emitting surface. In a top-view, the light-emitting surface has a diagonal length. The encapsulating layer covers the light-emitting element. The encapsulating layer has a curved light-output surface. The light-adjusting structure is disposed on the light-output of the encapsulating layer. The light-adjusting structure includes at least one light-adjusting layer. Moreover, an arc length of the at least one light-adjusting layer is greater than the diagonal length of the light-emitting surface of the light-emitting element.

### CROSS REFERENCE TO RELATED APPLICATIONS

This application claims the benefit of Taiwan Application No. 114106692, filed Feb. 25, 2025, the entirety of which is incorporated by reference herein.

### BACKGROUND

### Technical Field

The present disclosure is related to a light-emitting device.

### Description of the Related Art

Light-emitting diodes (LEDs) have several advantages, including their small size, high brightness, and low energy consumption. They are widely used in light-emitting devices.

However, the size of light-emitting diodes is continuously decreasing, resulting in some unresolved problems in the process of manufacturing light-emitting diodes, thereby affecting the performance of light-emitting devices. For example, the current packaging structure of light-emitting diodes still has problems such as limited light-emitting angle, uneven brightness, and poor module quality.

Therefore, how to further improve the light-emitting device of light-emitting diodes to enhance the performance of the light-emitting device is still one of the research topics currently being studied in the industry.

### SUMMARY

In accordance with some embodiments of the present disclosure, a light-emitting device is provided. The light-emitting device includes a substrate, a light-emitting element, an encapsulating layer and a light-adjusting structure. The light-emitting element is disposed on the substrate. The light-emitting element includes a light-emitting surface. In a top-view, the light-emitting surface has a diagonal length. The encapsulating layer covers the light-emitting element. The encapsulating layer has a curved light-output surface. The light-adjusting structure is disposed on the light-output of the encapsulating layer. The light-adjusting structure includes at least one light-adjusting layer. Moreover, an arc length of the at least one light-adjusting layer is greater than the diagonal length of the light-emitting surface of the light-emitting element.

A detailed description is given in the following embodiments with reference to the accompanying drawings.

### BRIEF DESCRIPTION OF THE DRAWINGS

The disclosure will be understood more fully from the detailed description given below and from the accompanying figures of embodiments of the disclosure. The figures are used to provide knowledge and understanding of embodiments of the disclosure and do not limit the scope of the disclosure to these specific embodiments. Furthermore, the figures are not necessarily drawn to scale. The patent or application file contains at least one drawing executed in color. Copies of this patent or patent application publication with color drawing(s) will be provided by the Office upon request and payment of the necessary fee.

The present disclosure may be more fully understood by reading the subsequent detailed description and examples with references made to the accompanying drawings, wherein:

FIG. 1 is a cross-sectional diagram of a light-emitting device in accordance with some embodiments of the present disclosure;

FIG. 2 is a top-view diagram of a light-emitting element of a light-emitting device in accordance with some embodiments of the present disclosure;

FIG. 3 is a cross-sectional diagram of a light-emitting device in accordance with some embodiments of the present disclosure;

FIG. 4 is a cross-sectional diagram of a light-emitting device in accordance with some embodiments of the present disclosure;

FIG. 5 is a cross-sectional diagram of a light-emitting device in accordance with some embodiments of the present disclosure;

FIG. 6 is a top-view diagram of a light-adjusting layer of the light-adjusting structure in accordance with some embodiments of the present disclosure;

FIG. 7A is a light pattern measurement diagram and a module image diagram of a light-emitting device in a Comparative Example;

FIG. 7B is a light pattern measurement diagram and a module image diagram of a light-emitting device in accordance with some embodiments of the present disclosure;

FIG. 8 is a cross-sectional diagram of a light-emitting device in accordance with some embodiments of the present disclosure;

FIG. 9 is a cross-sectional diagram of a light-emitting device in accordance with some embodiments of the present disclosure;

FIG. 10 is a cross-sectional diagram of a light-emitting device in accordance with some embodiments of the present disclosure;

FIG. 11 is a cross-sectional diagram of a light-emitting device in accordance with some embodiments of the present disclosure;

FIG. 12 is a cross-sectional diagram of a light-emitting device in accordance with some embodiments of the present disclosure;

FIG. 13 is a cross-sectional diagram of a light-emitting device in accordance with some embodiments of the present disclosure;

FIG. 14 is a cross-sectional diagram of a light-emitting device in accordance with some embodiments of the present disclosure;

FIG. 15 is a cross-sectional diagram of a light-emitting device in accordance with some embodiments of the present disclosure;

FIG. 16 is a cross-sectional diagram of a light-emitting device in accordance with some embodiments of the present disclosure;

FIG. 17 is a comparison result of brightness distribution of the light-emitting devices in accordance with some Comparative Examples and Examples of the present disclosure;

FIG. 18 is a schematic diagram of a backlight module in accordance with some embodiments of the present disclosure.

### DETAILED DESCRIPTION

The light-emitting devices according to the present disclosure are described in detail in the following description. It should be understood that in the following detailed description, for purposes of explanation, numerous specific details and embodiments are set forth in order to provide a thorough understanding of the present disclosure. The elements and configurations described in the following detailed description are set forth in order to clearly describe the present disclosure. These embodiments are used merely for the purpose of illustration, and the present disclosure is not limited thereto. In addition, different embodiments may use like and/or corresponding numerals to denote like and/or corresponding elements in order to clearly describe the present disclosure. However, the use of like and/or corresponding numerals of different embodiments does not suggest any correlation between different embodiments.

It should be understood that relative expressions may be used in the embodiments. For example, “lower”, “bottom”, “higher” or “top” are used to describe the position of one element relative to another. It should be appreciated that if a device is flipped upside down, an element that is “lower” will become an element that is “higher”. The present disclosure can be understood by referring to the following detailed description in connection with the accompanying drawings. The drawings are also regarded as part of the description of the present disclosure. It should be understood that the drawings of the present disclosure may be not drawn to scale. In fact, the size of the elements may be arbitrarily enlarged or reduced to clearly represent the features of the present disclosure.

Furthermore, the expression “a first material layer is disposed on or over a second material layer” may indicate that the first material layer is in direct contact with the second material layer, or it may indicate that the first material layer is in indirect contact with the second material layer. In the situation where the first material layer is in indirect contact with the second material layer, there may be one or more intermediate layers between the first material layer and the second material layer. However, the expression “the first material layer is directly disposed on or over the second material layer” means that the first material layer is in direct contact with the second material layer, and there is no intermediate element or layer between the first material layer and the second material layer.

Moreover, it should be understood that the ordinal numbers “first”, “second”, etc. mentioned in the specification or claims of the present application are used to name different elements or to distinguish different embodiments or scopes. They are not used to limit the upper or lower limit of the number of elements, nor are they used to limit the manufacturing sequence or disposing sequence of the elements.

In accordance with the embodiments of the present disclosure, regarding the term such as “disposed”, “connected with/to”, etc. referring to bonding and connection, unless specifically defined, these terms mean that two structures are in direct contact or two structures are not in direct contact, and other structures are provided to be disposed between the two structures. The terms for disposing and connecting may also include the case where both structures are movable or both structures are fixed.

In the following descriptions, terms “about”, “substantially” and “approximately” typically mean +/−10% of the stated value, or typically +/−5% of the stated value, or typically +/−3% of the stated value, or typically +/−2% of the stated value, or typically +/−1% of the stated value or typically +/−0.5% of the stated value. The expression “in a range greater than or equal to the first value and less than or equal to the second value” or “in a range between the first value and the second value” means that the range includes the first value, the second value, and other values in between.

Unless defined otherwise, all technical and scientific terms used herein have the same meaning as commonly understood by one of ordinary skill in the art to which the present disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

In accordance with some embodiments of the present disclosure, a light-emitting device is provided that includes a light-adjusting structure configured in a specific manner, thereby improving the light pattern performance of the light-emitting element and enhancing the module quality. Furthermore, in accordance with some embodiments of the present disclosure, the light-adjusting structure has good structural stability and is not easily peeled off from the encapsulating layer due to external forces. In accordance with some embodiments of the present disclosure, the light-adjusting structure includes several light-adjusting layers arranged in a specific ratio of size, thereby improving the light-emitting efficiency and light-emitting uniformity of the light-emitting element.

In accordance with some embodiments of the present disclosure, the light-emitting device described below can be applied to a backlight module (such as a backlight module of a display or a backlight module of a vehicle instrument panel), a lighting light-emitting module, a vehicle light-emitting module, etc., but the present disclosure is not limited thereto.

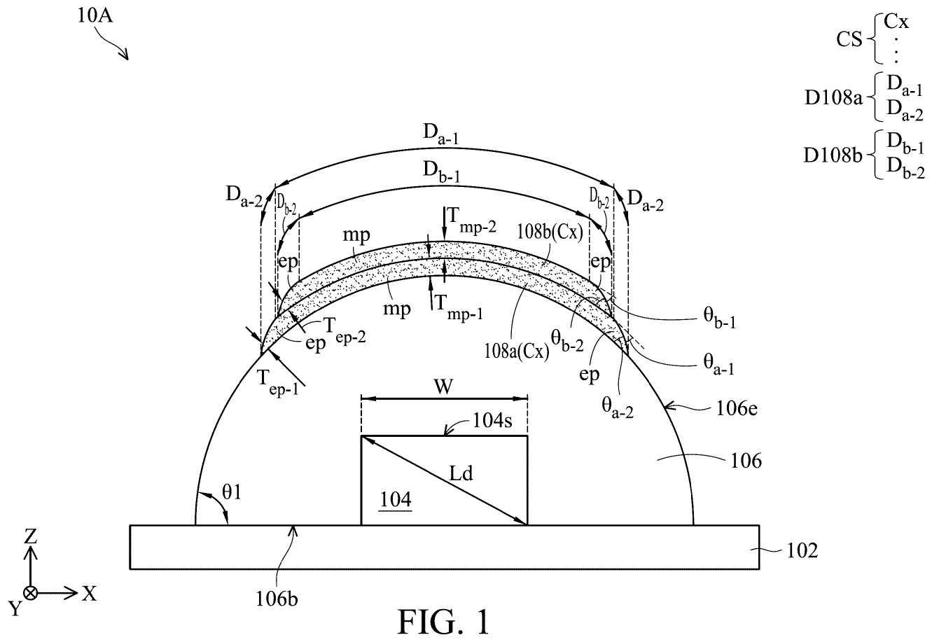

Refer to FIG. 1, which is a cross-sectional diagram of a light-emitting device 10A in accordance with some embodiments of the present disclosure. It should be understood that, for the sake of clarity, some elements of the light-emitting device may be omitted in the drawings, and only some elements are schematically illustrated. In accordance with some embodiments, additional features may be added to the light-emitting devices described below. In accordance with some embodiments, some features of the light-emitting device described below may be replaced or omitted.

As shown in FIG. 1, the light-emitting device 10A may include a substrate 102, a light-emitting element 104, an encapsulating layer 106 and a light-adjusting structure CS.

The substrate 102 is a substrate having a conductive circuit (not illustrated). The conductive circuit can be electrically connected to the light-emitting element 104 and electrically connected to an external power source through the conductive circuit, so as to transfer the externally supplied current to the light-emitting element 104. In accordance with some embodiments, the substrate 102 includes a flexible substrate, a rigid substrate, or a combination thereof. In accordance with some embodiments, the material of the substrate 102 may include glass, quartz, sapphire, ceramic, plastic, polyimide (PI), polycarbonate (PC), polyethylene terephthalate (PET), polypropylene (PP), another suitable material, or a combination thereof, but it is not limited thereto. In addition, the substrate 102 may be a light-transmitting substrate, a semi-light-transmitting substrate, or a non-light-transmitting substrate. In accordance with some embodiments, the substrate 102 may be a printed circuit board (PCB).

The light-emitting element 104 is disposed on the substrate 102 and electrically connected to the conductive circuit of the substrate 102. The light-emitting element 104 includes a light-emitting diode, such as a sub-millimeter light-emitting diode (mini-LED). In accordance with some embodiments, the light-emitting element 104 may be electrically connected to a driving element (not illustrated) disposed on the substrate 102. The driving element may include, for example, a thin-film transistor (TFT) or an integrated circuit (IC), but the present disclosure is not limited thereto. In accordance with some embodiments, the light-emitting element 104 may emit blue light, red light, green light, or another suitable color of light, but the present disclosure is not limited thereto. In accordance with some embodiments, the light-emitting element 104 may be a flip-chip light-emitting diode.

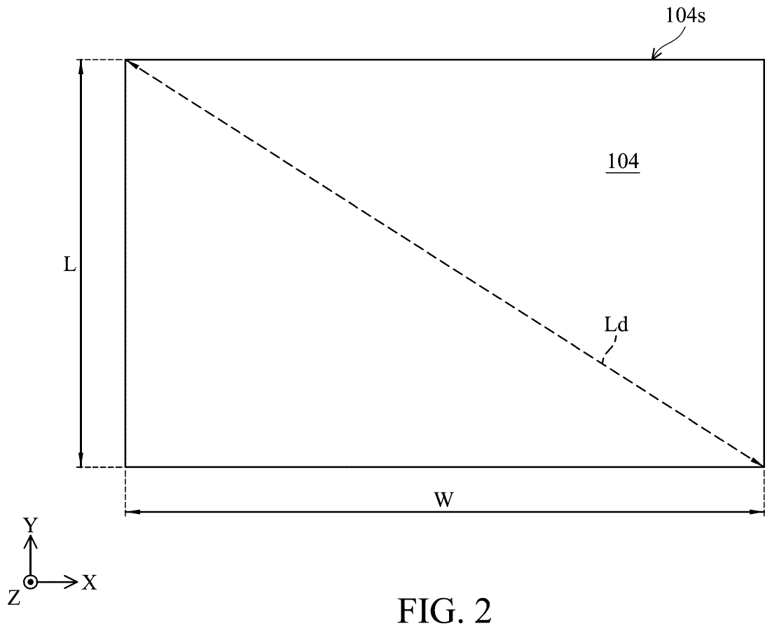

Furthermore, refer to FIG. 2, which is a top-view diagram of the light-emitting element 104 of the light-emitting device 10A in accordance with some embodiments of the present disclosure. As shown in FIG. 2, the light-emitting element 104 includes a light-emitting surface 104s, and in the top-view, the light-emitting surface 104s has a diagonal length Ld. In addition, the light-emitting surface 104s has a length L and a width W. In accordance with some embodiments, in the top-view, the light-emitting element 104 may be a rectangle, and Ld is the diagonal length of the rectangle light-emitting surface 104s. That is, the diagonal length Ld equals √(L²+W²), where L and W are the length and width of the light-emitting surface 104s, but the present disclosure is not limited thereto. In accordance with some other embodiments, in the top-view, the light-emitting element 104 may be circular, elliptical, or another suitable shape. In the embodiments where the light-emitting element 104 is circular, elliptical, or other shapes, the diagonal length Ld may be defined as the diagonal length of the smallest rectangle that can surround the shape.

Refer to FIG. 1. The encapsulating layer 106 covers the light-emitting element 104. The encapsulating layer 106 has a light-output surface 106e, and the light-output surface 106e is arc-shaped. In accordance with some embodiments, the encapsulation layer 106 may contact the top surface (e.g., including the light-emitting surface 104s) and the side surfaces of the light-emitting element 104. The encapsulation layer 106 can protect the light-emitting element 104, for example. It has a moisture-proof function or an insulation function, and can improve the reliability of the overall structure. Furthermore, an angle θ1 is formed between the light-output surface 106e and the bottom surface 106b of the encapsulation layer 106. The angle θ1 between the light-output surface 106e and the bottom surface 106b of the encapsulation layer 106 may be less than or equal to 90 degrees. In detail, in accordance with the embodiments of the present disclosure, the aforementioned angle θ1 refers to the angle between the tangent line of the light-output surface (arc surface) 106e and the bottom surface 106b of the encapsulating layer 106.

The encapsulation layer 106 may include a light-curing adhesive, a thermal-curing adhesive, a light-thermal-curing adhesive, or a combination thereof, but it is not limited thereto. In accordance with some embodiments, the material of the encapsulation layer 106 may include optical clear adhesive (OCA), optical clear resin (OCR), another suitable material, or a combination thereof, but it is not limited thereto. In accordance with some embodiments, the material of the encapsulation layer 106 may include silicone. The encapsulation layer 106 may be transparent or translucent. In accordance with some embodiments, the encapsulation layer 106 may include diffusion particles. In accordance with some embodiments, the diffusion particles may include inorganic particles, organic polymer particles, or a combination thereof. For example, the inorganic particles may include silicon oxide, titanium oxide, titanium dioxide, aluminum oxide, calcium carbonate, barium sulfate, boron nitride, zirconium dioxide, or any combination thereof, but the present disclosure is not limited thereto. For example, the inorganic particles may include solid silica or hollow silica or any combination thereof, but the present disclosure is not limited thereto. For example, the organic polymer particles may include polymethyl methacrylate (PMMA), polystyrene (PS), acrylonitrile-butadiene-styrene copolymer (ABS), polyurethane (PU) or any combination thereof, but the present disclosure is not limited thereto. In accordance with some embodiments, the encapsulation layer 106 may include phosphors, quantum dots or a combination of phosphors and quantum dots.

In FIG. 1, the light-adjusting structure CS is disposed on the light-output surface 106e of the encapsulating layer 106, and the light-adjusting structure CS includes at least one light-adjusting layer Cx. The light-adjusting layer Cx has an arc length that is greater than the diagonal length Ld of the light-emitting surface 104s of the light-emitting element 104. Furthermore, the light-adjusting layer Cx may be stacked on the light-output surface 106e of the encapsulating layer 106 and located just above the light-emitting element 104. In accordance with some embodiments, the light-adjusting layer Cx includes a light-shielding layer stacked structure, which is located above the light-emitting element 104 and on the light-output surface 106e of the encapsulating layer 106. The light-shielding layer stacked structure includes a plurality of light-shielding layers, and the thickness close to center of the light-shielding layer stacked structure is greater than the thickness close to the end of the light-shielding layer stacked structure. In the light-shielding layer stacked structure, the light-shielding layers have different sizes. For example, the arc lengths of the light-shielding layers are different and the arc length of each of the light-shielding layers is greater than the diagonal length Ld of the light-emitting surface 104s. In addition, the size of the light-shielding layers may be stacked from large to small or from small to large as the distance from the light-emitting surface 104s increases.

As shown in FIG. 1, taking the light-adjusting layer Cx including two stacked light-shielding layers as an example, the light-shielding layer stacked structure includes a light-shielding layer 108a and a light-shielding layer 108b, and the light-shielding layer 108b may be disposed on the light-shielding layer 108a. In detail, in this embodiment, the light-shielding layer 108a partially covers the light-output surface 106e of the encapsulating layer 106 and has an arc length D108a, which is greater than the diagonal length Ld of the light-emitting surface 104s; the light-shielding layer 108b is stacked on the surface of the light-shielding layer 108a and has an arc length D108b, which is also greater than the diagonal length Ld of the light-emitting surface 104s. Specifically, the arc length D108a is the arc length of the upper surface of the light-shielding layer 108a, and the arc length D108b is the arc length of the upper surface of the light-shielding layer 108b. In accordance with some other embodiments, the arc length of one of the light-shielding layer 108a and the light-shielding layer 108b is greater than the diagonal length Ld of the light-emitting surface 104s, and the arc length of the other one of the light-shielding layer 108a and the light-shielding layer 108b may be less than the diagonal length Ld of the light-emitting surface 104s. In accordance with some embodiments, from a top-view, the shapes of the light-shielding layer 108a and the light-shielding layer 108b may include circular, elliptical, rectangular, irregular or another suitable shape, but they are not limited thereto. Furthermore, the shapes of the light-shielding layer 108a and the light-shielding layer 108b may be similar, the same, or different.

In addition, as shown in FIG. 1, the ends of the light-shielding layer 108a and the light-shielding layer 108b may have a thickness gradient structure. In detail, the light-shielding layer 108a and the light-shielding layer 108b may respectively have a main portion mp and an end portion ep connected to the main portion mp. An arc length Da−1 of the main portion mp of the light-shielding layer 108a is greater than an arc length Da−2 of the end portion ep. An arc length Db−1 of the main portion mp of the light-shielding layer 108b is greater than an arc length Db−2 of the end portion ep. Specifically, the upper surface of the main portion mp of the light-shielding layer 108a has the arc length Da−1, and the upper surface of the end portion ep of the light-shielding layer 108a has the arc length Da−2; and the upper surface of the main portion mp of the light-shielding layer 108b has the arc length Db−1, and the upper surface of the end portion ep of the light-shielding layer 108b has the arc length Db−2. The arc length D108a of the upper surface the light-shielding layer 108a consists of the arc length Da−1 of the upper surface of the main portion mp and the arc length Da−2 of the upper surface of the end portion ep; and the arc length D108b of the upper surface of the light-shielding layer 108b consists of the arc length Db−1 of the upper surface of the main portion mp and the arc length Db−2 of the upper surface of the end portion ep. Furthermore, a thickness Tₘₚ₋₁ of the main portion mp of the light-shielding layer 108a may be greater than a thickness Tₑₚ₋₁ of the end portion ep, and a thickness Tₘₚ₋₂ of the main portion mp of the light-shielding layer 108b may be greater than a thickness Tₑₚ₋₂ of the end portion ep. In accordance with some embodiments, the thickness of the main portion mp of the light-shielding layer 108a may be substantially uniform. In accordance with some embodiments, the thickness of the main portion mp of the light-shielding layer 108a at both sides close to the end portions ep may be slightly smaller than the thickness of the central portion of the main portion mp.

Moreover, in accordance with some embodiments, a tangent angle θₐ₋₁ is formed between the surface of the end portion ep of the light-shielding layer 108a adjacent to the main portion mp and the surface of the main portion mp, an included angle θₐ₋₂ is formed between the surface of the end portion ep of the light-shielding layer 108a away from the main portion mp and the surface of the encapsulation layer 106, and the tangent angle θₐ₋₁ is greater than the included angle θₐ₋₂. In accordance with some embodiments, the range of the tangent angle θₐ₋₁ may be between 0 degrees and 90 degrees, and the range of the included angle θₐ₋₂ may be between 0 degrees and 90 degrees. Similarly, in accordance with some embodiments, a tangent angle θ_{b-1} is formed between the surface of the end portion ep of the light-shielding layer 108b adjacent to the main portion mp and the surface of the main portion mp, an included angle θ_{b-2} is formed between the surface of the end portion ep of the light-shielding layer 108a away from the main portion mp and the surface of the light-shielding layer 108a, and the tangent angle θ_{b-1} is greater than the included angle θ_{b-2}. In accordance with some embodiments, the range of the tangent angle θ_{b-1} may be between 0 degrees and 90 degrees, and the range of the included angle θ_{b-2} may be between 0 degrees and 90 degrees.

In accordance with the embodiments of the present disclosure, the aforementioned end portion ep can be defined as a portion approximately one-fifth or one-quarter of the total arc length measured inward from the edge of the light-shielding layer 108a (or the light-shielding layer 108b), and the main portion mp corresponds to the portion of the light-shielding layer 108a (or the light-shielding layer 108b) other than the end portions ep at both sides. Furthermore, the aforementioned thickness Tₘₚ₋₁ and thickness Tₘₚ₋₂ may be thicknesses measured at any position of the main portion mp, and the aforementioned thickness Tₑₚ₋₁ and thickness Tₑₚ₋₂ may be thicknesses measured at any position of the end portion ep.

The material of the light-shielding layer 108a and the light-shielding layer 108b may include a reflective material, for example, a high reflectivity material with a reflectivity greater than 90%. In accordance with some embodiments, the light-shielding layer 108a and the light-shielding layer 108b may include a matrix and a high reflectivity material disposed on the surface of the matrix or in the matrix. In accordance with some embodiments, the material of the matrix may include an organic material, such as epoxy resin, silicone, acrylic resin such as polymethylmetacrylate (PMMA), benzocyclobutene (BCB), polyimide, polyester, polydimethylsiloxane (PDMS), polyethylene terephthalate (PET), polycarbonate (PC), another suitable material, or a combination thereof, but it is not limited thereto. In accordance with some embodiments, the high reflectivity material may include a white reflective material, so that the light-shielding layer 108a and the light-shielding layer 108b appear white, and the white reflective material may be an oxide, such as titanium dioxide (TiO₂), zirconium oxide (ZrO₂), zinc oxide (ZnO), silicon dioxide (SiO₂), or aluminum oxide (A1₂O₃). In accordance with some embodiments, the high reflectivity material may include silver (Ag), aluminum (Al), titanium (Ti), another suitable material, or a combination thereof, but it is not limited thereto. In accordance with some embodiments, the high reflectivity material may include heat-curing high reflectivity silicone resin, but it is not limited thereto. In accordance with some embodiments, the light-shielding layer 108a and the light-shielding layer 108b may be partially reflective and partially transmissive.

In accordance with some embodiments, the light-shielding layer 108a and the light-shielding layer 108b may be formed by a printing process such as a screen printing process or an inkjet printing process, a coating process, a deposition process, an evaporation process, a sputtering process, another suitable process, or a combination thereof. In accordance with some embodiments, the light-shielding layer 108a and the light-shielding layer 108b may be formed by an inkjet printing process.

It is noting that the light-adjusting structure CS with the aforementioned configuration (for example, including the light-shielding layer 108a and the light-shielding layer 108b as the light-adjusting layer Cx or including the light-shielding layer 108a and the light-shielding layer 108b with a specific design of the main portion mp and end portions ep) can improve the light pattern performance of the light-emitting element 104 and enhance the overall module quality of the light-emitting device 10A.

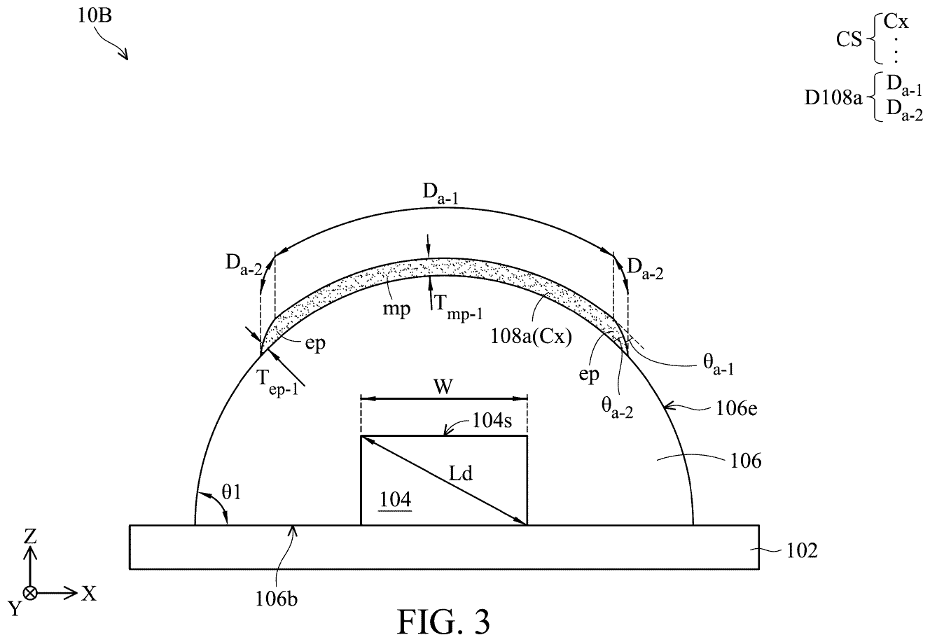

Next, refer to FIG. 3, which is a cross-sectional diagram of a light-emitting device 10B in accordance with some other embodiments of the present disclosure. It should be understood that elements that are identical or similar to those mentioned above will be denoted by the same or similar numerals, and their materials, features and functions are the same or similar to those described above, and thus will not be repeated in the following description.

As shown in FIG. 3, the light-emitting device 10B is substantially similar to the light-emitting device 10A. Compared with the light-emitting device 10A, the light-adjusting structure CS of the light-emitting device 10B only includes a single light-shielding layer 108a as a light-adjusting layer Cx, which is stacked on the light-output surface 106e of the encapsulation layer 106. In this embodiment, the light-adjusting layer Cx is the light-shielding layer 108a, and an arc length D108a of the light-shielding layer 108a is greater than a diagonal length Ld of the light-emitting surface 104s. The arc length D108a is an arc length of the upper surface of the light-shielding layer 108a. Similarly, the end portion ep of the light-shielding layer 108a may have a thickness gradient structure. In detail, the light-shielding layer 108a includes a main portion mp and an end portion ep, the upper surface of the main portion mp has an arc length Dₐ₋₁, and the upper surface of the end portion ep has an arc length Dₐ₋₂. Moreover, the arc length Dₐ₋₁ of the main portion mp is greater than the arc length Dₐ₋₂ of the end portion ep, and the thickness Tₘₚ₋₁ of the main portion mp of the light-shielding layer 108a is greater than the thickness Tₑₚ₋₁ of the end portion ep. That is, the arc length D108a of the upper surface of the light-shielding layer 108a consists of the arc length Dₐ₋₁ of the upper surface of the main portion mp and the arc length Dₐ₋₂ of the upper surface of the end portion ep. Furthermore, in accordance with some embodiments, a tangent angle θₐ₋₁ is formed between the surface of the end portion ep of the light-shielding layer 108a adjacent to the main portion mp and the surface of the main portion mp, an included angle θₐ₋₂ is formed between the surface of the end portion ep of the light-shielding layer 108a away from the main portion mp and the surface of the encapsulation layer 106, and the tangent angle θₐ₋₁ is greater than the included angle θₐ₋₂.

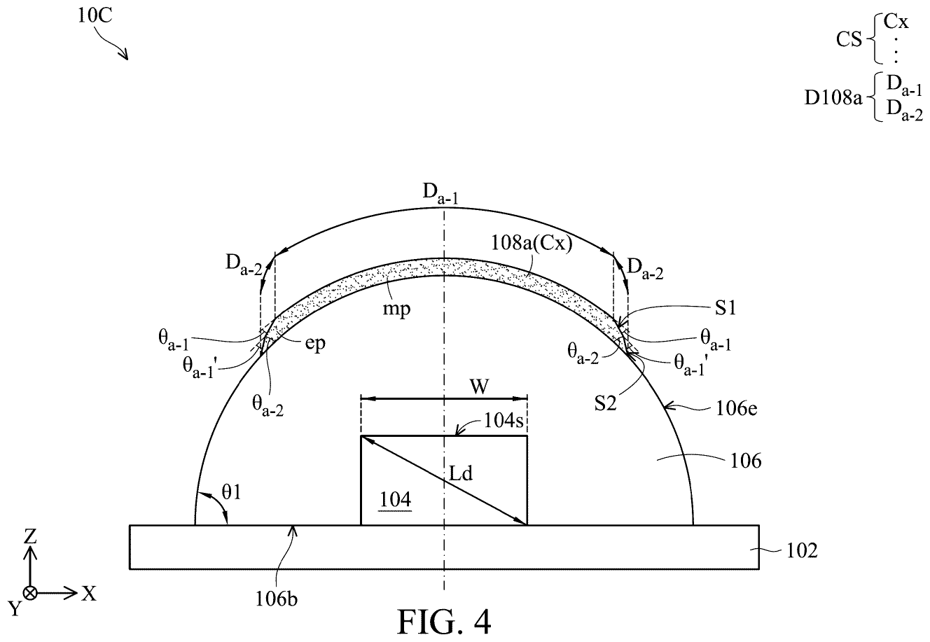

Next, refer to FIG. 4, which is a cross-sectional diagram of a light-emitting device 10C in accordance with some other embodiments of the present disclosure. As shown in FIG. 4, the light-emitting device 10C is substantially similar to the light-emitting device 10B. Compared with the light-emitting device 10B, the end portion ep of the light-shielding layer 108a of the light-emitting device 10C has two thickness gradient structures. A surface S1 and a surface S2 of the two thickness gradient structures corresponding to the end portion ep of the light-shielding layer 108a may have different slopes. In detail, in this embodiment, a tangent angle θₐ₋₁ is formed between the surface of the end portion ep of the light-shielding layer 108a adjacent to the main portion mp and the surface of the main portion mp, a tangent angle θₐ₋₁′ is formed between the two connecting surface S1 and surface S2 of the end portion ep of the light-shielding layer 108a farther away from the main portion mp, and an included angle θₐ₋₂ is formed between the surface S2 of the end portion ep of the light-shielding layer 108a away from the main portion mp and the surface of the encapsulation layer 106. In addition, the tangent angle θₐ₋₁ and the tangent angle θₐ₋₁′ are both greater than the included angle θa−2, and the included angle θₐ₋₂ is greater than the tangent angle θₐ₋₁′. In accordance with some embodiments, the range of the tangent angle θₐ₋₁ may be between 0 degrees and 90 degrees, the range of the tangent angle θₐ₋₁′ may be between 0 degrees and 90 degrees, and the range of the included angle θₐ₋₂ may be between 0 degrees and 90 degrees.

It should be understood that although the figures only illustrate an embodiment in which the end portion of the light-shielding layer has one or two thickness gradient structures, the present disclosure is not limited thereto. In accordance with some embodiments, the end portion of the light-shielding layer may have, for example, three, four, or five thickness gradient structures, but it is not limited thereto.

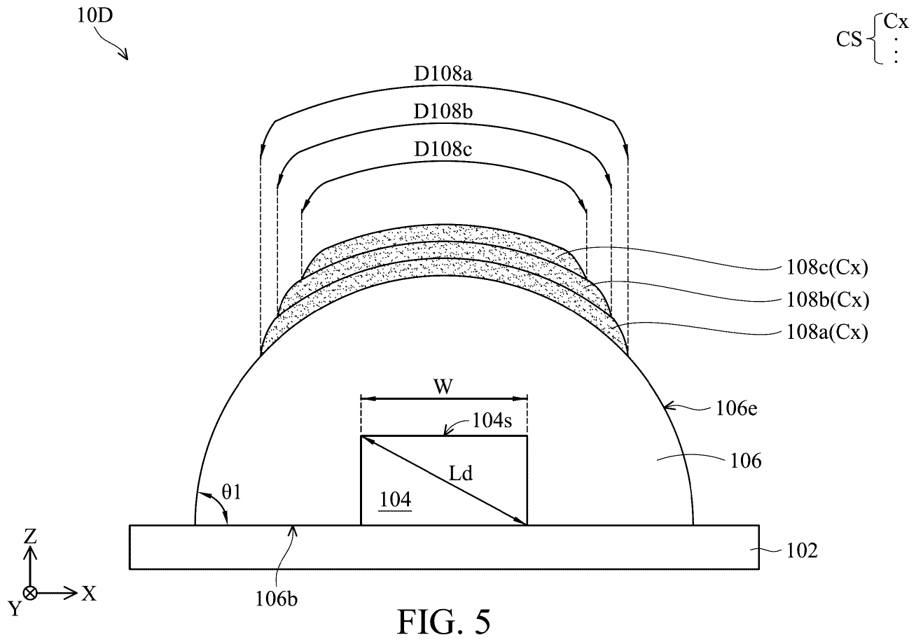

Next, refer to FIG. 5, which is a cross-sectional diagram of a light-emitting device 10D in accordance with some other embodiments of the present disclosure. As shown in FIG. 5, the light-emitting device 10D is substantially similar to the light-emitting device 10A. Compared with the light-emitting device 10A, the light-adjusting layer Cx of the light-emitting device 10D further includes a light-shielding layer 108c, and the light-shielding layer 108c is disposed on the light-shielding layer 108b. The light-shielding layer 108c also partially covers the light-output surface 106e of the encapsulating layer 106 and has an arc length D108c. In accordance with some embodiments, the arc length D108c of the light-shielding layer 108c is greater than the diagonal length Ld of the light-emitting surface 104s of the light-emitting element 104. In accordance with some embodiments, the arc length D108c of the light-shielding layer 108c is equal to the diagonal length Ld of the light-emitting surface 104s. In accordance with some embodiments, the arc length D108c of the light-shielding layer 108c is less than the diagonal length Ld of the light-emitting surface 104s. In accordance with some embodiments, the shape of the light-shielding layer 108c may include a circle, an ellipse, a rectangle, an irregular shape or another suitable shape, but it is not limited thereto. Furthermore, the shape of the light-shielding layer 108c may be the same as or different from the shapes of the light-shielding layer 108a and the light-shielding layer 108b. In addition, the end portions of the light-shielding layer 108c may also have a thickness gradient structure similar to the aforementioned light-shielding layer 108a and the light-shielding layer 108b. The material and manufacturing method of the light-shielding layer 108c may be the same or similar to the material and manufacturing method of the aforementioned light-shielding layer 108a and the light-shielding layer 108b, which will not be repeated here.

Furthermore, it should be understood that although the figures only illustrate the embodiments in which the light-adjusting structure CS includes one, two or three light-shielding layers as the light-adjusting layer Cx, the present disclosure is not limited thereto. In accordance with some embodiments, the light-adjusting layer Cx has other numbers of light-shielding layers, such as four, five, six or another suitable number of light-shielding layers.

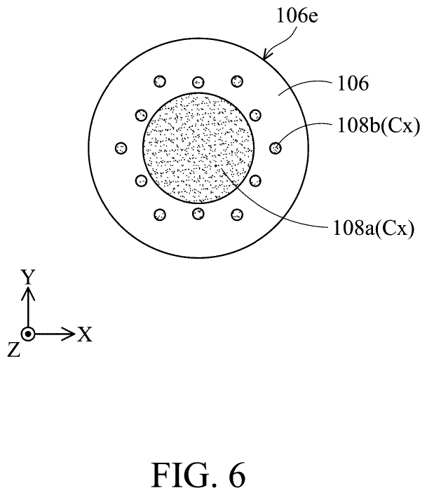

Refer to FIG. 6, which is a top-view diagram of a light-adjusting layer Cx of the light-adjusting structure CS in accordance with some embodiments of the present disclosure. As shown in FIG. 6, in accordance with some embodiments, the light-adjusting layer Cx may be distributed discontinuously on the light-output surface 106e of the encapsulation layer 106. For example, in accordance with some embodiments, the light-adjusting layer Cx includes a light-shielding layer 108a and a light-shielding layer 108b. The light-shielding layer 108a partially covers the light-output surface 106e of the encapsulating layer 106 and corresponds to the light-emitting element (not illustrated). Similarly, the arc length D108a of the light-shielding layer 108a is greater than the diagonal length Ld of the light-emitting surface 104s. The light-shielding layer 108b is disposed on the light-output surface 106e of the encapsulating layer 106 and surrounds the light-shielding layer 108a. The light-shielding layer 108b is a patterned light-shielding layer. In accordance with some embodiments, the patterned light-shielding layer 108b may have a plurality of sub-portions. For example, in a top-view, the light-shielding layer 108b may have a plurality of separated sub-portions, and these sub-portions may surround the light-shielding layer 108a or the light-emitting element (not illustrated). In accordance with some embodiments, the patterned light-shielding layer 108b may have a plurality of sub-portions arranged in a circular shape, an elliptical shape, a rectangular shape, another suitable shape, or a combination thereof. Furthermore, in accordance with some embodiments, the light-shielding layer 108b may partially overlap with the light-shielding layer 108a.

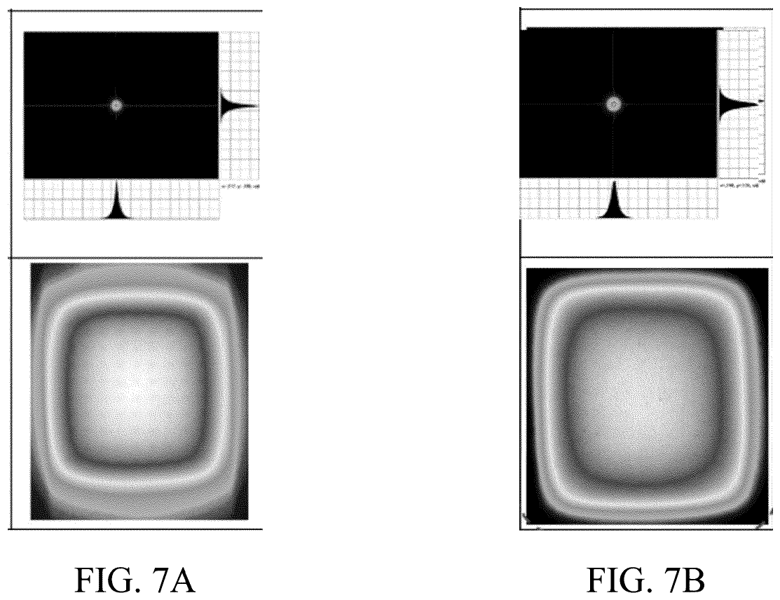

Next, refer to FIG. 7A and FIG. 7B. FIG. 7A is a light pattern measurement diagram and a module image diagram of a light-emitting device in a Comparative Example. FIG. 7B is a light pattern measurement diagram of a light-emitting device and a module image diagram in accordance with some embodiments of the present disclosure. Specifically, FIG. 7A shows a light pattern measurement diagram of a light-emitting device using a single light-shielding layer as the light-adjusting layer (for example, as a Comparative Example) and an image result applied to a backlight module, and FIG. 7B shows a light pattern measurement diagram of a light-emitting device using double light-shielding layers as the light-adjusting layer (for example, the light-emitting device 10A shown in FIG. 1) and an image result applied to a backlight module. The light pattern in FIG. 7B is more uniform than that in FIG. 7A. This effect of the multiple light-shielding layers helps to make the visual effect of the surface light source more uniform.

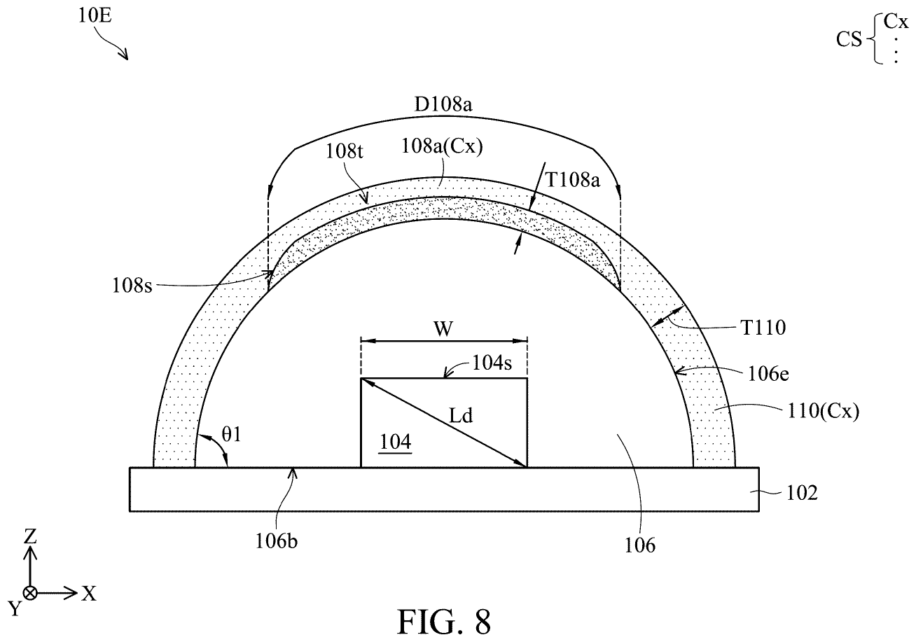

Refer to FIG. 8, which is a cross-sectional diagram of a light-emitting device 10E in accordance with some embodiments of the present disclosure. As shown in FIG. 8, the light-emitting device 10E is substantially similar to the light-emitting device 10B. Compared with the light-emitting device 10B, the light-adjusting layer Cx of the light-emitting device 10E further includes a protection layer 110. In this embodiment, the light-shielding layer 108a and the protection layer 110 may serve as the light-adjusting layers Cx. The protection layer 110 may be disposed on the encapsulating layer 106 and cover the light-shielding layer 108a. The protection layer 110 may completely extend onto the light-output surface 106e of the encapsulating layer 106. The protection layer 110 can completely cover the light-shielding layer 108a. In accordance with some embodiments, the protection layer 110 may be in contact with the top surface 108t and the side surface 108s of the light-shielding layer 108a, and may be in contact with the light-output surface 106e of the encapsulation layer 106 and the substrate 102.

In accordance with some embodiments, a thickness T110 of the protection layer 110 may be greater than the thickness T108a of the light-shielding layer 108a (e.g., may be the thickness Tₘₚ₋₁ of the main portion mp or the thickness Tₑₚ₋₁ of the end portion ep of the light-shielding layer 108a shown in FIG. 1). Specifically, in accordance with some embodiments, the thickness T110 of the protection layer 110 may be between 10 μm and 50 μm, for example, 15 μm, 20 μm, 25 μm, 30 μm, 35 μm, 40 μm or 45 μm, but it is not limited thereto. In accordance with some embodiments, the thickness T108a of the light-shielding layer 108a may be between 10 μm and 200 μm. Furthermore, in accordance with some embodiments, the hardness of the protection layer 110 is less than the hardness of the encapsulation layer 106. In accordance with some embodiments, the viscosity of the protection layer 110 is less than the viscosity of the encapsulation layer 106. In addition, the refractive index of the protection layer 110 may be different from the refractive index of the light-shielding layer 108a. In accordance with some embodiments, the refractive index of the protection layer 110 may be less than the refractive index of the light-shielding layer 108a. In accordance with some embodiments, the refractive index of the protection layer 110 may be greater than the refractive index of the light-shielding layer 108a.

In accordance with the embodiments of the present disclosure, the aforementioned thickness T110 refers to the maximum thickness of the protection layer 110 on the encapsulating layer 106, and the aforementioned thickness T108a refers to the maximum thickness of the light-shielding layer 108a on the encapsulating layer 106.

The protection layer 110 may include a light-curing adhesive, a heat-curing adhesive, a light-heat-curing adhesive, or a combination thereof, but it is not limited thereto. In accordance with some embodiments, the material of the protection layer 110 may include optical clear adhesive (OCA), optical clear resin (OCR), another suitable material, or a combination thereof, but it is not limited thereto. In accordance with some embodiments, the material of the protection layer 110 may include silicone. The protection layer 110 may be transparent or translucent. Furthermore, the material of the protection layer 110 may be the same as or similar to that of the encapsulation layer 106.

In accordance with some embodiments, the protection layer 110 may be formed by a printing process, a coating process, a deposition process, another suitable process, or a combination thereof.

It is noting that the light-adjusting structure CS having the aforementioned configuration (for example, including the light-shielding layer 108a and the protection layer 110 as the light-adjusting layer Cx) can reduce the risk of separation of the light-adjusting structure CS from the encapsulating layer 106, so that the light-adjusting structure CS is not easily peeled off from the encapsulating layer 106 due to external force, thereby improving the reliability of the overall structure of the light-emitting device.

In addition, it should be understood that although FIG. 8 and subsequent figures only illustrate the light-adjusting structure CS having a single-layer light-shielding layer 108a, the light-adjusting structure CS may also include multiple light-shielding layers as the light-adjusting layer Cx (as shown in FIG. 1 or FIG. 5).

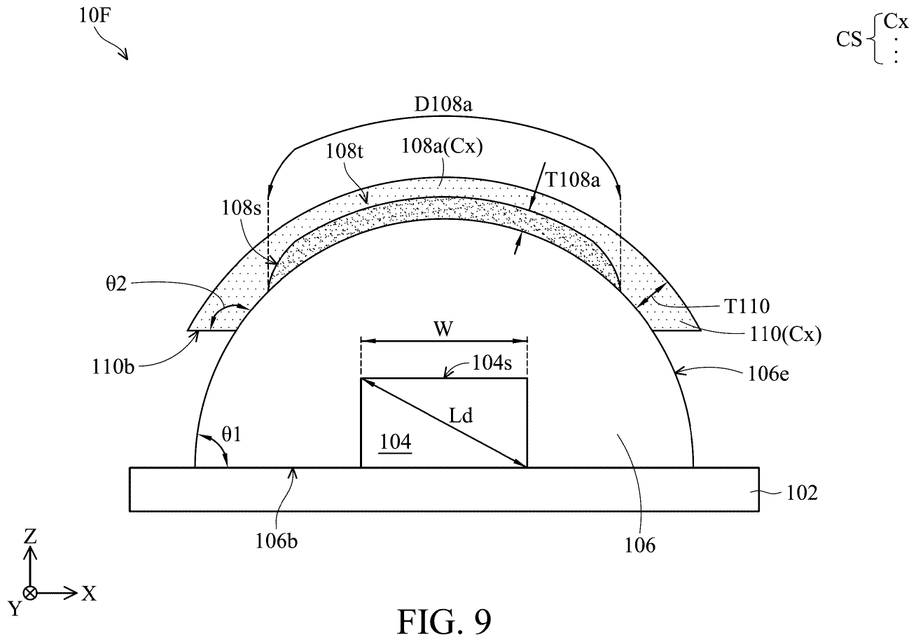

Next, refer to FIG. 9, which is a cross-sectional diagram of a light-emitting device 10F in accordance with some other embodiments of the present disclosure. As shown in FIG. 9, the light-emitting device 10F is substantially similar to the light-emitting device 10E. Compared with the light-emitting device 10E, the protection layer 110 in the light-emitting device 10F partially extends over the light-output surface 106e of the encapsulation layer 106. In this embodiment, the protection layer 110 may contact the top surface 108t and the side surface 108s of the light-shielding layer 108a and may contact the light-output surface 106e of the encapsulation layer 106, but is not in contact with the substrate 102. In this embodiment, an included angle θ2 is formed between the bottom surface 110b of the protection layer 110 and the light-output surface 106e of the encapsulating layer 106. The included angle θ2 may be greater than 90 degrees and less than or equal to 150 degrees, for example, 95 degrees, 100 degrees, 105 degrees, 110 degrees, 115 degrees, 120 degrees, 125 degrees, 130 degrees, 135 degrees, 140 degrees or 145 degrees, but it is not limited thereto.

In accordance with some embodiments, the material of the protection layer 110 may be coated on the light-output surface 106e of the encapsulating layer 106, and patterned by one or more photolithography processes and/or etching processes to form the protection layer 110 having the aforementioned structure. In accordance with some embodiments, the photolithography process may include photoresist coating (e.g., spin coating), soft baking, hard baking, mask alignment, exposure, post-exposure baking, photoresist development, cleaning and drying, but it is not limited thereto. The etching process may include a dry etching process or a wet etching process, but it is not limited thereto.

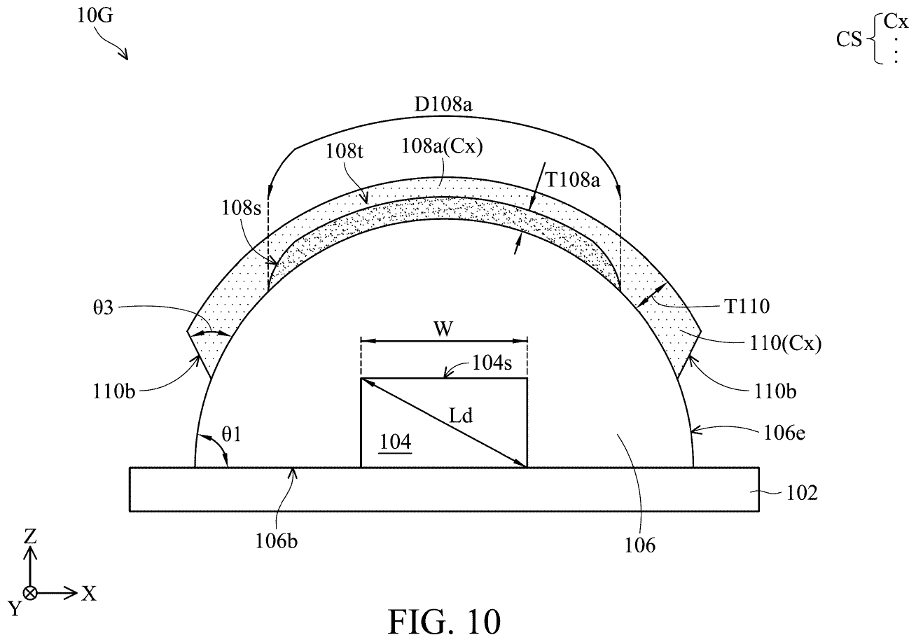

Refer to FIG. 10, which is a cross-sectional diagram of a light-emitting device 10G in accordance with some other embodiments of the present disclosure. As shown in FIG. 10, the light-emitting device 10G is substantially similar to the light-emitting device 10E. Compared with the light-emitting device 10E, the protection layer 110 in the light-emitting device 10G partially extends over the light-output surface 106e of the encapsulation layer 106. In this embodiment, the protection layer 110 may contact the top surface 108t and the side surface 108s of the light-shielding layer 108a and may contact the light-output surface 106e of the encapsulation layer 106, but is not in contact with the substrate 102. In this embodiment, an included angle θ3 is formed between the bottom surface 110b of the protection layer 110 and the light-output surface 106e of the encapsulating layer 106. The included angle θ3 may be greater than or equal to 30 degrees and less than 90 degrees, for example, 35 degrees, 40 degrees, 45 degrees, 50 degrees, 55 degrees, 60 degrees, 65 degrees, 70 degrees, 75 degrees, 80 degrees or 85 degrees, but it is not limited thereto.

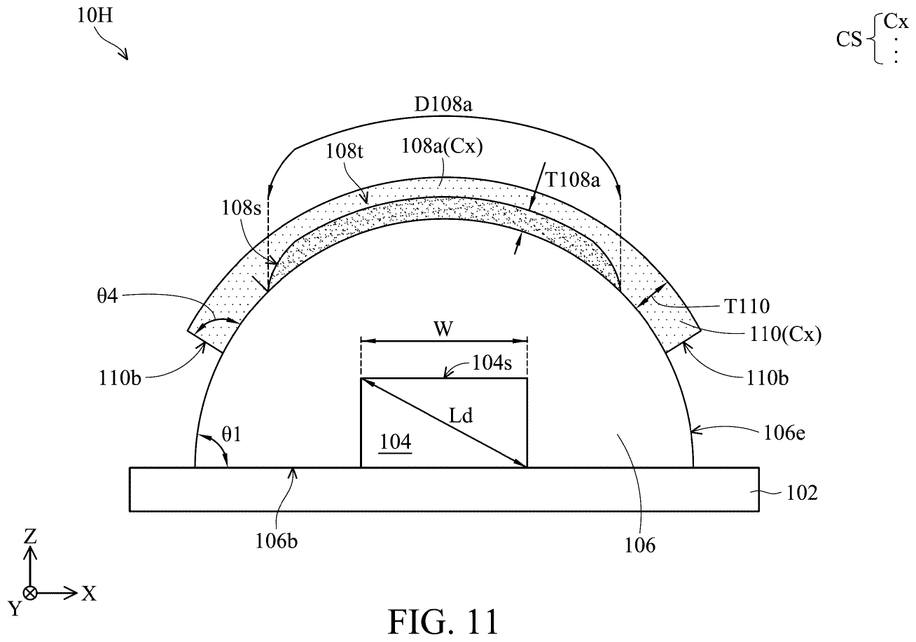

Refer to FIG. 11, which is a cross-sectional diagram of a light-emitting device 10H in accordance with some other embodiments of the present disclosure. As shown in FIG. 10, the light-emitting device 10H is substantially similar to the light-emitting device 10E. Compared with the light-emitting device 10E, the protection layer 110 in the light-emitting device 10H partially extends over the light-output surface 106e of the encapsulation layer 106. In this embodiment, the protection layer 110 may contact the top surface 108t and the side surface 108s of the light-shielding layer 108a and may contact the light-output surface 106e of the encapsulation layer 106, but is not in contact with the substrate 102. In this embodiment, an included angle θ4 is formed between the bottom surface 110b of the protection layer 110 and the light-output surface 106e of the encapsulating layer 106. The included angle θ4 may be substantially equal to 90 degrees.

In the light-emitting devices 10A to 10H, the light-emitting element 104 can emit blue light or white light. For example, the light-emitting element 104 includes a blue light-emitting diode. For example, the light-emitting element 104 includes a white light LED package structure. The white light LED package structure includes a blue light-emitting diode and a wavelength conversion material. In some embodiments, the white light LED package structure is a chip scale packaging (CSP) structure, in which the blue light-emitting diode is a flip-chip light-emitting diode, and the wavelength conversion material is coated on the surface of the blue light-emitting diode.

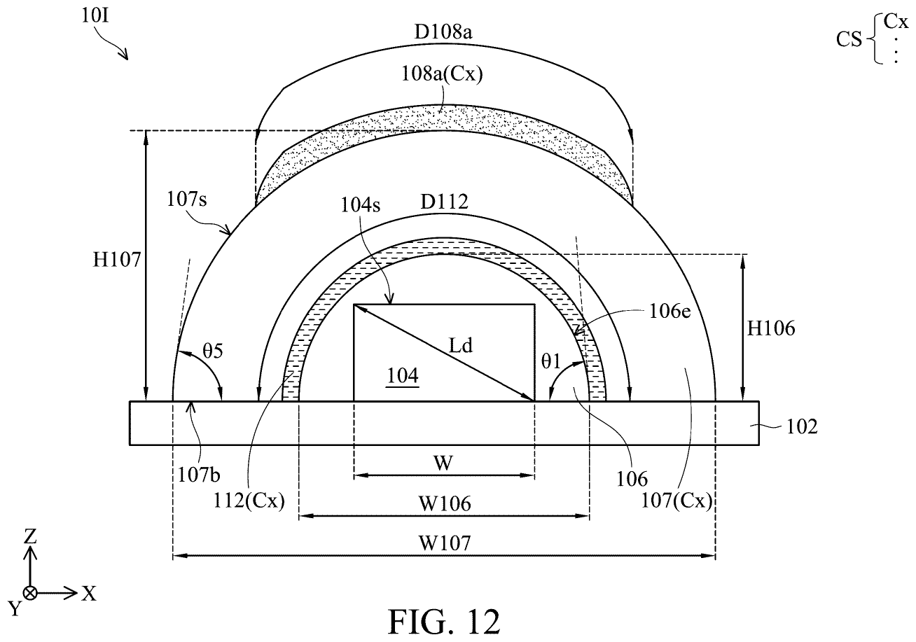

Next, refer to FIG. 12, which is a cross-sectional diagram of a light-emitting device 10I in accordance with some other embodiments of the present disclosure. As shown in FIG. 12, the light-emitting device 10I is substantially similar to the light-emitting device 10B. Compared with the light-emitting device 10B, the light-emitting device 10I further includes a wavelength conversion layer 112 and a light-transmitting layer 107. In this embodiment, the light-shielding layer 108a, the light-transmitting layer 107 and the wavelength conversion layer 112 may serve as the light-adjusting layers Cx. The light-transmitting layer 107 may be disposed on the encapsulating layer 106, the light-shielding layer 108a may partially cover the light-output surface of the light-transmitting layer 107 and have an arc length D108a. The arc length D108a is greater than the diagonal length Ld of the light-emitting surface 104s. The wavelength conversion layer 112 may be disposed between the light-transmitting layer 107 and the encapsulating layer 106, and the wavelength conversion layer 112 may completely extend onto the light-output surface 106e of the encapsulating layer 106. In detail, the wavelength conversion layer 112 may be in contact with the light-output surface 106e of the encapsulating layer 106 and the substrate 102. Furthermore, the wavelength conversion layer 112 has an arc length D112, and the arc length D112 is greater than the diagonal length Ld of the light-emitting surface 104s.

The light-transmitting layer 107 may completely cover the wavelength conversion layer 112, and the light-transmitting layer 107 may be in contact with the wavelength conversion layer 112 and the substrate 102. Moreover, an included angle θ5 is formed between the side surface 107s and the bottom surface 107b of the light-transmitting layer 107. The included angle θ5 between the side surface 107s and the bottom surface 107b of the light-transmitting layer 107 may be less than or equal to 90 degrees. Specifically, in accordance with the embodiments of the present disclosure, the aforementioned included angle θ5 refers to the angle between the tangent line of the side surface (curved surface) 107s and the bottom surface 107b of the light-transmitting layer 107.

In addition, in this embodiment, the encapsulating layer 106 has a height H106 and a width W106, and the ratio of the height H106 to the width W106 may be greater than 0 and less than or equal to 0.5 (i.e., 0<H106/W106≤0.5), for example, 0.05, 0.1, 0.15, 0.2, 0.25, 0.3, 0.35, 0.4 or 0.45, but it is not limited thereto. Furthermore, in this embodiment, the light-transmitting layer 107 has a height H107 and a width W107, and the ratio of the height H107 to the width W107 may be greater than 0 and less than or equal to 0.5 (i.e., 0<H107/W107≤0.5), for example, 0.05, 0.1, 0.15, 0.2, 0.25, 0.3, 0.35, 0.4 or 0.45, but it is not limited thereto. It is noting that when the height and width ratio of the encapsulation layer 106 and the light-transmitting layer 107 falls within the above range (0<H106/W106≤0.5 and 0<H107/W107≤0.5), the luminous efficiency and uniformity of the light-emitting element 104 can be effectively improved.

In accordance with the embodiments of the present disclosure, the aforementioned height H106 refers to the maximum height of the encapsulating layer 106 in the normal direction of the substrate 102 (for example, the Z direction in the figure); the width W106 refers to the maximum width of the encapsulating layer 106 in the direction perpendicular to the normal direction of the substrate 102 (for example, the X direction in the figure). Similarly, the aforementioned height H107 refers to the maximum height of the light-transmitting layer 107 in the normal direction of the substrate 102 (e.g., the Z direction in the figure); the width W107 refers to the maximum width of the light-transmitting layer 107 in the direction perpendicular to the normal direction of the substrate 102 (e.g., the X direction in the figure).

The wavelength conversion layer 112 may convert the light generated by the light-emitting element 104 into light having a specific color or a specific wavelength. The wavelength conversion layer 112 may include a matrix and one or more wavelength conversion substances dispersed in the matrix. In accordance with some embodiments, the matrix may include a polymer material, but it is not limited thereto. In accordance with some embodiments, the wavelength conversion material may include phosphor, quantum dot material, or a combination thereof, but it is not limited thereto. Furthermore, in accordance with some embodiments, the light-emitting element 104 may be a light-emitting diode that emits blue light, and the wavelength conversion layer 112 may include yellow phosphor. For example, the yellow phosphor may be yttrium aluminum garnet (YAG) phosphor, so the light-emitting device 10I may emit white light, but the present disclosure is not limited thereto. In accordance with some embodiments, the wavelength conversion layer 112 may include red phosphor, green phosphor, a phosphor of another suitable color, or a combination thereof, but it is not limited thereto. In accordance with some embodiments, the wavelength conversion layer 112 may include two different red phosphors, green phosphors, a phosphor of another suitable color, or a combination thereof, but it is not limited thereto. In accordance with some embodiments, the wavelength conversion layer 112 may include green phosphor and red phosphor. For example, the wavelength conversion layer 112 may include green phosphor β-SiAlON:Eu²⁺ and red phosphor K₂SiF₆:Mn⁴⁺. In accordance with some embodiments, the wavelength conversion layer 112 may include a combination of a green phosphor and two red phosphors. For example, the wavelength conversion layer 112 may include green phosphor β-SiAlON:Eu²⁺ and red phosphors K₂SiF₆:Mn⁴⁺ and (Sr,Ca)AlSiN₃:Eu²⁺.

The light-transmitting layer 107 can protect the wavelength conversion layer 112, for example. It has a moisture-proof function or an insulation function, and can improve the reliability of the overall structure. The light-transmitting layer 107 may include a light-curing adhesive, a heat-curing adhesive, a light-heat-curing adhesive, or a combination thereof, but it is not limited thereto. In accordance with some embodiments, the material of the light-transmitting layer 107 may include optical clear adhesive (OCA), optical clear resin (OCR), another suitable material, or a combination thereof, but it is not limited thereto. In accordance with some embodiments, the material of the light-transmitting layer 107 may include silicone. The light-transmitting layer 107 may be transparent or translucent. In accordance with some embodiments, the light-transmitting layer 107 may include diffusion particles. In accordance with some embodiments, the diffusion particles may include inorganic particles, organic polymer particles, or a combination thereof. For example, the inorganic particles may include silicon oxide, titanium oxide, titanium dioxide, aluminum oxide, calcium carbonate, barium sulfate, boron nitride, zirconium dioxide, or any combination thereof, but the present disclosure is not limited thereto. For example, the inorganic particles may include solid silica or hollow silica or any combination thereof, but the present disclosure is not limited thereto. For example, the organic polymer particles may include polymethyl methacrylate (PMMA), polystyrene (PS), acrylonitrile-butadiene-styrene copolymer (ABS), polyurethane (PU) or any combination thereof, but the present disclosure is not limited thereto.

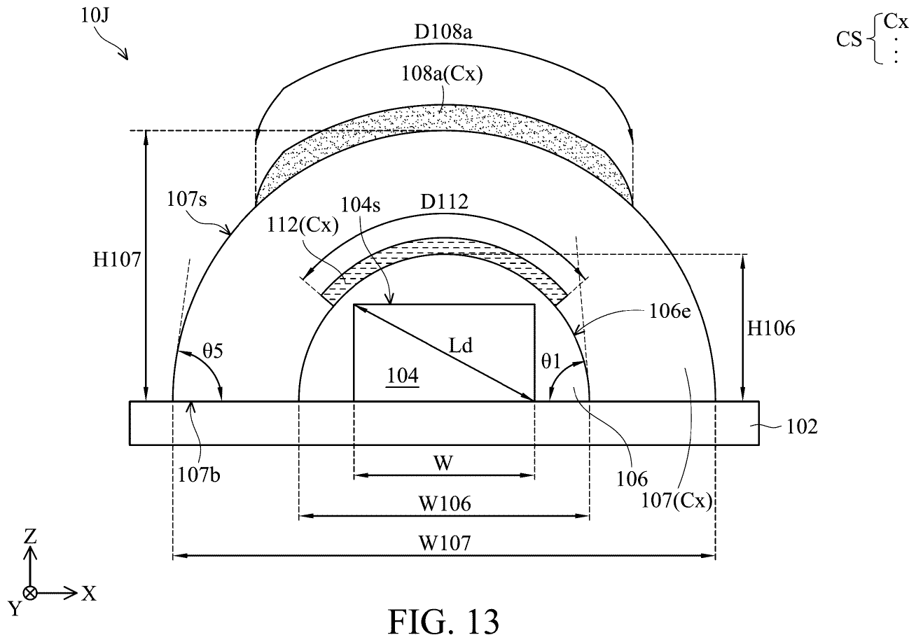

Refer to FIG. 13, which is a cross-sectional diagram of a light-emitting device 10J in accordance with some other embodiments of the present disclosure. As shown in FIG. 13, the light-emitting device 10J is substantially similar to the light-emitting device 10I. Compared with the light-emitting device 10I, the wavelength conversion layer 112 in the light-emitting device 10J does not cover the entire light-output surface 106e of the encapsulating layer 106, but only partially covers the light-output surface 106e of the encapsulating layer 106. In this embodiment, the wavelength conversion layer 112 may be in contact with the light-output surface 106e of the encapsulating layer 106, but is not in contact with the substrate 102. Furthermore, the wavelength conversion layer 112 has an arc length D112, and the arc length D112 may be greater than the diagonal length Ld of the light-emitting surface 104s.

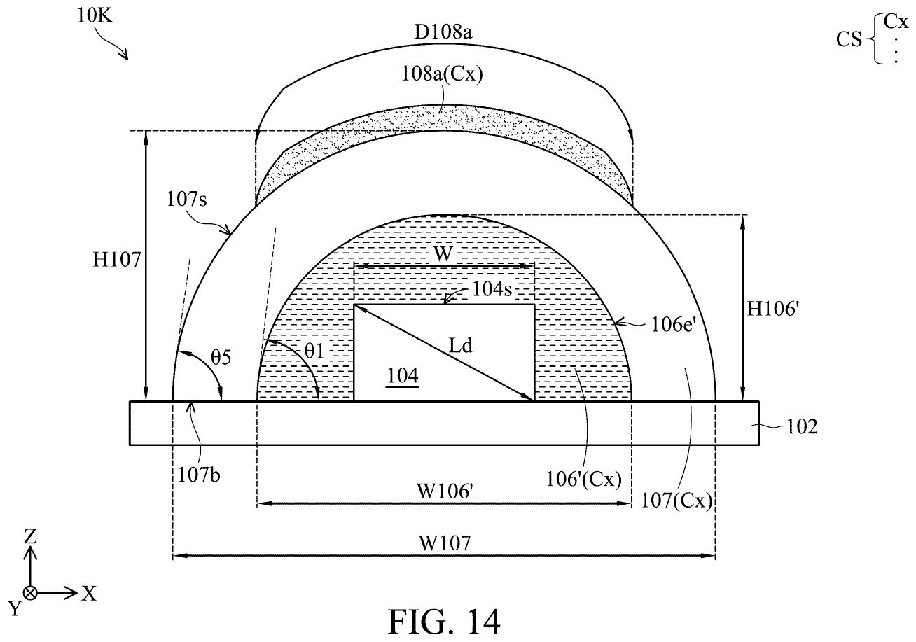

Refer to FIG. 14, which is a cross-sectional diagram of a light-emitting device 10K in accordance with some other embodiments of the present disclosure. As shown in FIG. 14, in accordance with some embodiments, the light-emitting device 10K may include an encapsulating layer 106′, and the encapsulating layer 106′ may include a wavelength conversion material. In this embodiment, the encapsulation layer 106′, the light-shielding layer 108a and the light-transmitting layer 107 can serve as the light-adjusting layers Cx. Compared with the light-emitting device 10I or the light-emitting device 10J, in this embodiment, the wavelength conversion layer 112 may not be additionally provided. Since the encapsulating layer 106′ already has a wavelength conversion function, the light generated by the light-emitting element 104 can be converted into light with a specific color or a specific wavelength. The encapsulation layer 106′ may contact the top surface (e.g., including the light-emitting surface 104s) and the side surfaces of the light-emitting element 104. The encapsulation layer 106′ can protect the light-emitting element 104, for example, having a moisture-proof function or an insulating function, which can improve the reliability of the overall structure. Furthermore, an included angle θ1 is also formed between the light-output surface 106e and the bottom surface of the encapsulation layer 106′ may also have, and the included angle θ1 between the light-output surface 106e′ and the bottom surface of the encapsulation layer 106′ may be less than or equal to 90 degrees.

In this embodiment, the encapsulating layer 106′ has a height H106′ and a width W106′, and the ratio of the height H106′ to the width W106′ may be greater than 0 and less than or equal to 0.5 (i.e., 0<H106′/W106′≤0.5), for example, 0.05, 0.1, 0.15, 0.2, 0.25, 0.3, 0.35, 0.4 or 0.45, but it is not limited thereto. It is noting that when the height and width ratio of the encapsulation layer 106′ falls within the above range (0<H106′/W106″≤0.5), the luminous efficiency and luminous uniformity of the light-emitting element 104 can be effectively improved.

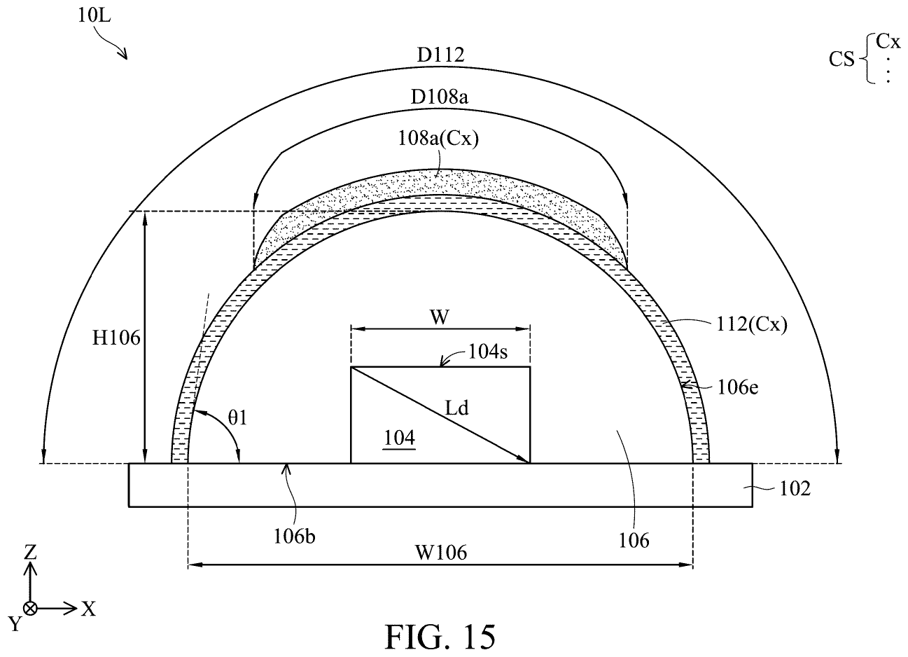

Refer to FIG. 15, which is a cross-sectional diagram of a light-emitting device 10L in accordance with some other embodiments of the present disclosure. As shown in FIG. 15, the light-emitting device 10L is substantially similar to the light-emitting device 10B. Compared with the light-emitting device 10B, the light-emitting device 10L further includes a wavelength conversion layer 112. In this embodiment, the light-shielding layer 108a and the wavelength conversion layer 112 can serve as the light-adjusting layers Cx. The wavelength conversion layer 112 may be disposed on the encapsulating layer 106, and the wavelength conversion layer 112 may completely extend onto the light-output surface 106e of the encapsulating layer 106. Furthermore, the light-shielding layer 108a may be disposed on the wavelength conversion layer 112 and partially cover the wavelength conversion layer 112. In detail, the wavelength conversion layer 112 may be in contact with the light-output surface 106e of the encapsulating layer 106 and the substrate 102. Furthermore, the wavelength conversion layer 112 has an arc length D112, and the arc length D112 is greater than the diagonal length Ld of the light-emitting surface 104s. In this embodiment, the arc length D112 of the wavelength conversion layer 112 is greater than the arc length D108a of the light-shielding layer 108a.

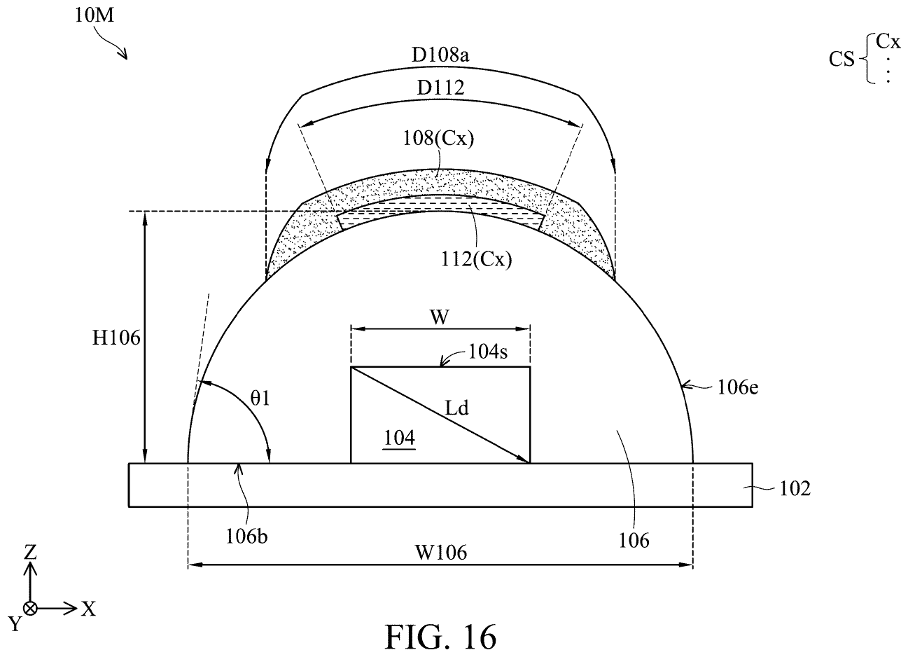

Refer to FIG. 16, which is a cross-sectional diagram of a light-emitting device 10M in accordance with some other embodiments of the present disclosure. As shown in FIG. 16, the light-emitting device 10M is substantially similar to the light-emitting device 10L. Compared with the light-emitting device 10L, the wavelength conversion layer 112 partially extends onto the light-output surface 106e of the encapsulation layer 106 in the light-emitting device 10M. Furthermore, the light-shielding layer 108a may be disposed on the wavelength conversion layer 112 and completely cover the wavelength conversion layer 112. In detail, the wavelength conversion layer 112 may partially contact the light-output surface 106e of the encapsulation layer 106, but is not in contact with the substrate 102. Furthermore, the wavelength conversion layer 112 has an arc length D112, and the arc length D112 is greater than the diagonal length Ld of the light-emitting surface 104s. In this embodiment, the arc length D112 of the wavelength conversion layer 112 is smaller than the arc length D108a of the light-shielding layer 108a.

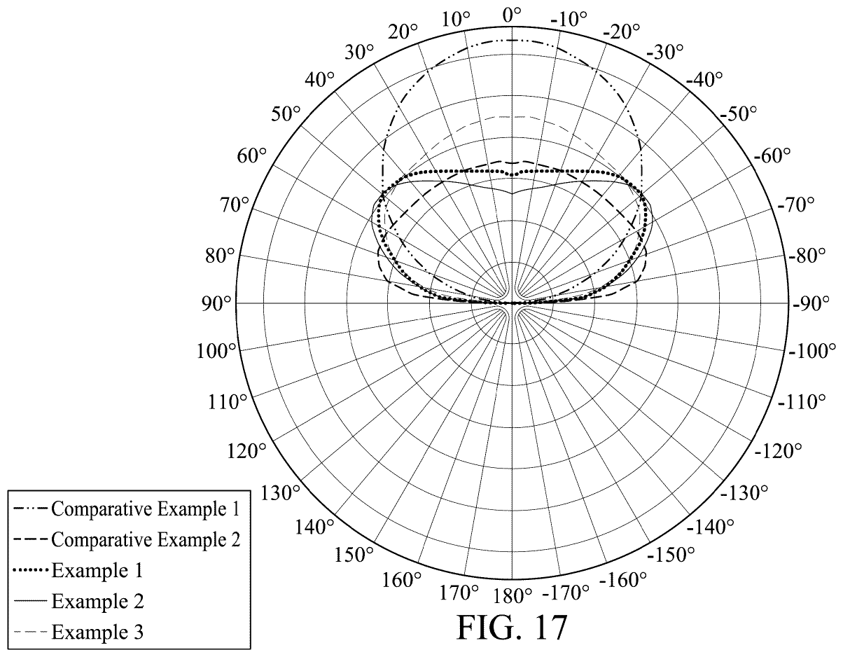

Next, refer to FIG. 17, which is a comparison result of brightness distribution of the light-emitting devices according to some Comparative Examples (Comparative Example 1, Comparative Example 2) and Examples of the present disclosure (Example 1, Example 2 and Example 3). Specifically, Comparative Example 1 is the brightness distribution result of a traditional light-emitting device in which a light-adjusting layer is not provided on the surface of the encapsulating layer; Comparative Example 2 is the brightness distribution result of a traditional light-emitting device in which only a wavelength conversion layer is disposed on the surface of the encapsulating layer; Example 1 is the brightness distribution result of the light-emitting device 10I as shown in FIG. 12; Example 2 is the brightness distribution result of the light-emitting device 10K as shown in FIG. 13; and Example 3 is the brightness distribution result of the light-emitting device 10L as shown in FIG. 15. Furthermore, the above test results are obtained by simulation using Light Tools simulation software.

As shown in FIG. 17, compared with Comparative Examples 1 and 2, the light-emitting devices of Examples 1, 2 and 3 have larger light-emitting angles and better brightness uniformity when applied to backlight modules. Furthermore, Examples 1 to 3 can provide a better luminous angle of lateral light, and can appropriately supplement the weak light area between the light-emitting elements to provide uniform brightness. The light-emitting devices of Examples 1 to 3 can be used with different optical distances and pitches. For example, the structures of Example 1 and Example 2 are suitable for designing a light panel module with a larger pitch between light-emitting elements.

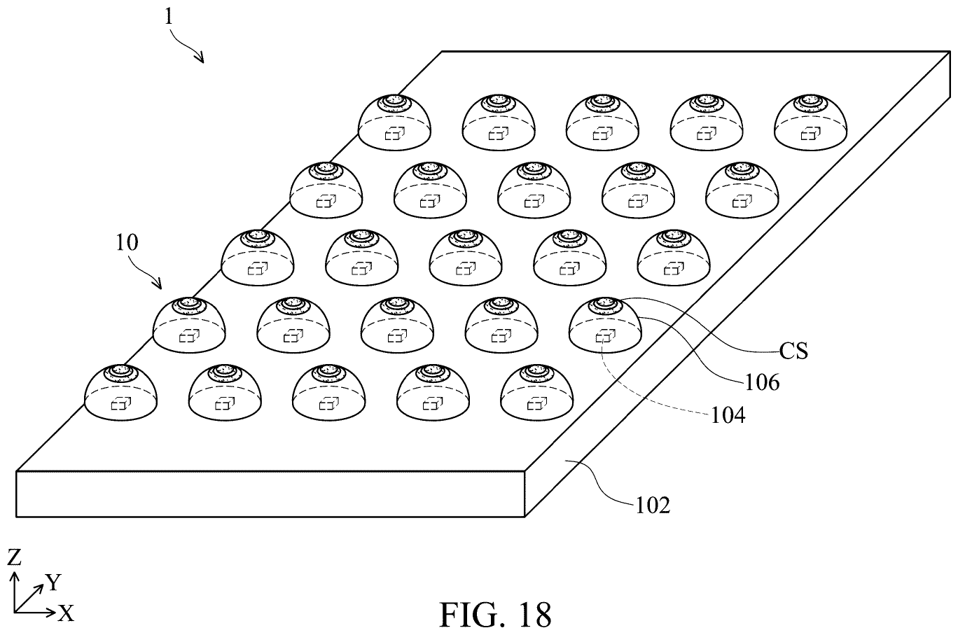

Refer to FIG. 18, which is a schematic diagram of a backlight module 1 in accordance with some embodiments of the present disclosure. As shown in FIG. 18, the backlight module 1 may include a substrate 102 and a plurality of light-emitting devices 10 disposed on the substrate 102. The light-emitting device 10 may have the structure of any one of the light-emitting devices 10A to 10M described above. The light-emitting device 10 includes a light-emitting element 104, an encapsulating layer 106 and a light-adjusting structure CS. A plurality of light-emitting devices 10 may be arranged in an array, for example, arranged with a first pitch (not illustrated) in the X direction and with a second pitch (not illustrated) in the Y direction. The first pitch may be the same as or different from the second pitch. In accordance with some embodiments, the light-emitting device 10 may emit white light or blue light. In accordance with some embodiments, the backlight module 1 may further include an optical component (not illustrated) disposed above the light-emitting device 10. The optical component may include a diffusion film, a brightness enhancement film, a wavelength conversion layer or another suitable optical film, but it is not limited thereto.

To summarize the above, the light-emitting device provided by the embodiments of the present disclosure includes a light-adjusting structure configured in a specific manner, thereby improving the light pattern performance of the light-emitting element and enhancing the module quality. Furthermore, in accordance with some embodiments of the present disclosure, the light-adjusting structure has good structural stability and is not easily peeled off from the encapsulating layer due to external forces. In accordance with some embodiments of the present disclosure, the light-adjusting structure includes several light-adjusting layers arranged in a specific ratio of size, thereby improving the light-emitting efficiency and light-emitting uniformity of the light-emitting element.

Although some embodiments of the present disclosure and their advantages have been described in detail, it should be understood that various changes, substitutions and alterations can be made herein without departing from the spirit and scope of the present disclosure as defined by the appended claims. The features of the various embodiments can be used in any combination as long as they do not depart from the spirit and scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Thus, the appended claims are intended to include within their scope such processes, machines, manufacture, compositions of matter, means, methods or steps. Moreover, each claim constitutes an individual embodiment, and the claimed scope of the present disclosure includes the combinations of the claims and embodiments. The scope of protection of the present disclosure is subject to the definition of the scope of the appended claims. Any embodiment or claim of the present disclosure does not need to meet all the purposes, advantages, and features disclosed in the present disclosure.

What is claimed is:

1. A light-emitting device, comprising:
a substrate;
a light-emitting element disposed on the substrate, wherein the light-emitting element comprises a light-emitting surface, and in a top-view, the light-emitting surface has a diagonal length;
an encapsulation layer covering the light-emitting element, wherein the encapsulation layer has a light-output surface having a curve shape; and
a light-adjusting structure disposed on the light-output surface of the encapsulation layer, wherein the light-adjusting structure comprises at least one light-adjusting layer, wherein the at least one light-adjusting layer has an arc length greater than the diagonal length of the light-emitting surface of the light-emitting element.

2. The light-emitting device as claimed in claim 1, wherein the at least one light-adjusting layer is stacked on the light-output surface or distributed discontinuously on the light-output surface.

3. The light-emitting device as claimed in claim 1, wherein the at least one light-adjusting layer comprises at least one light-shielding layer, one or more light-transmitting layers, one or more wavelength conversion layers, one or more protection layers, or a combination thereof.

4. The light-emitting device as claimed in claim 1, wherein the at least one light-adjusting layer comprises:
a first light-shielding layer partially covering the light-output surface of the encapsulation layer and having a first arc length, wherein the first arc length is greater than the diagonal length of the light-emitting surface; and
a second light-shielding layer stacked on a surface of the first light-shielding layer and having a second arc length, wherein the first arc length is greater than the second arc length, and the second arc length is greater than the diagonal length of the light-emitting surface, and wherein the arc length includes the first arc length or the second arc length.

5. The light-emitting device as claimed in claim 1, wherein the at least one light-adjusting layer comprises:
a first light-shielding layer partially covering the light-output surface of the encapsulation layer and corresponding to the light-emitting element, the first light-shielding layer having a first arc length, wherein the first arc length is greater than the diagonal length of the light-emitting surface; and
a second light-shielding layer disposed on the light-output surface of the encapsulation layer and surrounding the first light-shielding layer, wherein the second light-shielding layer is a patterned light-shielding layer.

6. The light-emitting device as claimed in claim 5 wherein the patterned light-shielding layer has a plurality of separated sub-portions, and the plurality of separated sub-portions surround the first light-shielding layer.

7. The light-emitting device as claimed in claim 5, wherein the patterned light-shielding layer has a plurality of sub-portions in a circular shape, an elliptical shape, a rectangular shape, or a combination thereof.

8. The light-emitting device as claimed in claim 1, wherein the at least one light-adjusting layer comprises:
a light-shielding layer partially covering the light-output surface of the encapsulation layer and having an arc length, wherein the arc length of the light-shielding layer is greater than the diagonal length of the light-emitting surface; and
a protection layer disposed on the encapsulation layer and covering the light-shielding layer, wherein the protection layer partially or completely extends onto the light-output surface of the encapsulation layer.

9. The light-emitting device as claimed in claim 8, wherein a hardness of the protection layer is less than a hardness of the encapsulation layer.

10. The light-emitting device as claimed in claim 8, wherein a viscosity of the protection layer is less than a viscosity of the encapsulation layer.

11. The light-emitting device as claimed in claim 1, wherein the at least one light-adjusting layer further comprises:
a light-transmitting layer disposed on the encapsulation layer; and
a light-shielding layer partially covering a light-output surface of the light-transmitting layer and having an arc length, wherein the arc length of the light-transmitting layer is greater than the diagonal length of the light-emitting surface.

12. The light-emitting device as claimed in claim 11, wherein the at least one light-adjusting layer further comprises:
a wavelength conversion layer disposed between the light-transmitting layer and the encapsulation layer, wherein the wavelength conversion layer partially or completely extends onto the light-output surface of the encapsulation layer.

13. The light-emitting device as claimed in claim 11, wherein the encapsulation layer comprises a wavelength conversion material.

14. The light-emitting device as claimed in claim 12, wherein an arc length of the wavelength conversion layer is greater than or equal to the diagonal length of the light-emitting surface.

15. The light-emitting device as claimed in claim 1, wherein a ratio of a height of the encapsulation layer to a width of the encapsulation layer is less than or equal to 0.5.

16. The light-emitting device as claimed in claim 11, wherein a ratio of a height of the light-transmitting layer to a width of the light-transmitting layer is less than or equal to 0.5.

17. The light-emitting device as claimed in claim 1, wherein the at least one light-adjusting layer further comprises:
a wavelength conversion layer disposed on the encapsulation layer, wherein the wavelength conversion layer partially or completely extends onto the light-output surface of the encapsulation layer; and
a light-shielding layer disposed on the wavelength conversion layer and partially or completely covering the wavelength conversion layer.

18. The light-emitting device as claimed in claim 1, wherein the at least one light-adjusting layer comprises:
a light-shielding layer partially covering the light-output surface of the encapsulation layer and having a main portion and an end portion connected to the main portion, wherein an arc length of the main portion is greater than an arc length of the end portion, and a thickness of the main portion is greater than a thickness of the end portion.

19. The light-emitting device as claimed in claim 18, wherein a tangent angle is formed between a surface of the end portion adjacent to the main portion and a surface of the main portion, an included angle is formed between a surface of the end portion away from the main portion and a surface of the encapsulation layer, and the tangent angle is greater than the included angle.

20. The light-emitting device as claimed in claim 2, wherein the at least one light-adjusting layer comprises a light-shielding layer stacked structure, the position of which corresponds to the light-emitting element and is located on the light-output surface of the encapsulation layer, wherein the light-shielding layer stacking structure comprises a plurality of light-shielding layers, and a central thickness of the light-shielding layer stacked structure is greater than an end thickness of the light-shielding layer stacked structure.
